(19) United States
(12) Patent Application Publication
(10) Pub. No.: US 2026/0164982 A1
(43) Pub. Date: Jun. 11, 2026

(54) Display Device

(71) Applicant: LG Display Co., Ltd., Seoul (KR)

(72) Inventors: Jaewoo Kim, Gimpo-si (KR); KwangSoo Kim, Incheon (KR)

(21) Appl. No.: 19/311,254

(22) Filed: Aug. 27, 2025

(30) Foreign Application Priority Data
Dec. 10, 2024 (KR) 10-2024-0182608

(51) Int. Cl. H10K 59/65

(52) U.S. Cl. CPC H10K 59/65

(57) ABSTRACT

A display device includes a display panel including a display area and an optical are. The display device further includes a back plate disposed below the display panel. The display device further includes a first reinforcement pattern which encloses the optical area and is a closed curve line on the plane. The first reinforcement pattern is disposed on the same layer as the back plate and the back plate is disposed between the optical area and the first reinforcement pattern on the plane. A display device including an optical area in which a plurality of reinforcement patterns is disposed to improve the rigidity.

### CROSS-REFERENCE TO RELATED APPLICATIONS

This application claims the priority of Republic of Korea Patent Application No. 10-2024-0182608 filed on Dec. 10, 2024, which is hereby incorporated by reference in its entirety.

### BACKGROUND

### Field

The present disclosure relates to a display device, and more particularly, to a display device including an optical area.

### Description of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### SUMMARY

An object to be achieved by the present disclosure is to provide a display device including an optical area in which a plurality of reinforcement patterns is disposed to improve the rigidity.

An object to be achieved by the present disclosure is to provide a display device which optimizes the process by simplifying the structure of the display device.

Objects of the present disclosure are not limited to the above-mentioned objects, and other objects, which are not mentioned above, can be clearly understood by those skilled in the art from the following descriptions.

According to an embodiment of the present disclosure, there is provided a display device. The display device includes a display panel including a display area and an optical are. The display device further includes a back plate disposed below the display panel. The display device further includes a first reinforcement pattern which encloses the optical area and is a closed curve line on the plane. The first reinforcement pattern is disposed on the same layer as the back plate and the back plate is disposed between the optical area and the first reinforcement pattern on the plane.

Other detailed matters of the exemplary embodiments are included in the detailed description and the drawings.

According to the exemplary embodiment of the present disclosure, a first reinforcement pattern and a plurality of extension reinforcement patterns are disposed on the same layer as the back plate to improve the rigidity of the back plate and the display panel in the vicinity of the optical area.

According to the exemplary embodiment of the present disclosure, at least some of the plurality of reinforcement patterns and an additional plate are integrally configured to optimize the process, thereby implementing a uni-material.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic plan view of a display device according to an exemplary embodiment of the present disclosure;

FIGS. 2 and 3 are enlarged plan views of an area X of FIG. 1 according to an exemplary embodiment of the present disclosure;

FIGS. 4A to 4D are views illustrating various structures of a reinforcement pattern of the present disclosure;

FIG. 5 is a cross-sectional view taken along a line A-B of FIG. 1 according to an exemplary embodiment of the present disclosure;

FIG. 6 is a view simply illustrating a process of forming an optical area in a display device according to an exemplary embodiment of the present disclosure;

FIG. 7 is a view illustrating a stress applied to a back plate in a peripheral area of an optical area according to an exemplary embodiment of the present disclosure;

FIG. 8 is a cross-sectional view of an area Y of FIG. 5 according to an exemplary embodiment of the present disclosure;

FIG. 9 is a cross-sectional view of an area Z of FIG. 5 according to an exemplary embodiment of the present disclosure;

FIG. 10 is a cross-sectional view of a part of a display device according to another exemplary embodiment of the present disclosure; and

FIG. 11 is a view illustrating a stress applied to a back plate in a peripheral area of an optical area of display devices according to Comparative Example and Examples and an improvement rate.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

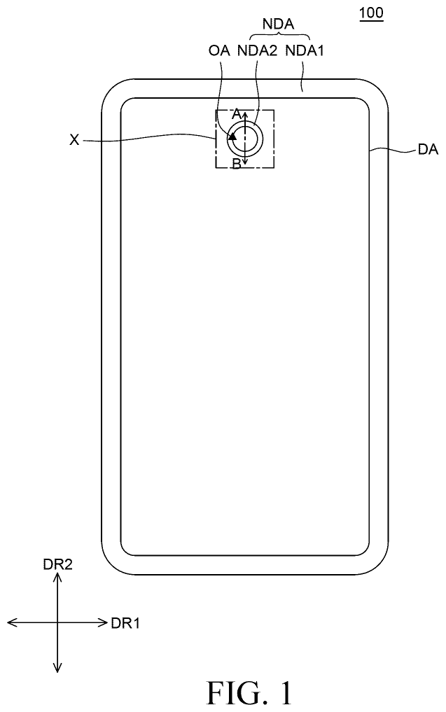

FIG. 1 is a schematic plan view of a display device according to an exemplary embodiment of the present disclosure.

The display device according to various exemplary embodiments of the present disclosure will be described as follows:

Referring to FIG. 1, a display device 100 according to a first exemplary embodiment of the present disclosure may include an optical module and a display panel. For example, the optical module includes a sensor and the sensor includes a camera sensor, a distance sensing sensor, or a face recognition sensor, but is not limited thereto.

The display panel may include a display area DA and a non-display area NDA.

The display area DA may be an area where images are displayed. The non-display area NDA is adjacent to the display area DA or encloses the display area DA. For example, the non-display area NDA may be a non-active area or a bezel area.

The display area DA in the display device 100 may include a plurality of sub pixels SP. A sub pixel SP may include a pixel circuit which is configured by a switching transistor, a driving transistor, and a light emitting diode.

The display device 100 according to the first exemplary embodiment of the present disclosure may be an organic light emitting diode (OLED) display, or a quantum dot display, a micro LED display, but is not limited thereto.

At least one optical area OA may be disposed in the display area DA. In the optical area OA, at least one optical device may be disposed. The optical device may be a camera sensor, a distance sensing sensor, or a face recognition sensor, but is not limited thereto.

The optical area OA is disposed in the display area DA so that the non-display area NDA of the display panel may be reduced and the display area DA may be expanded or widened. Products with an expanded display area DA may improve users'screen immersion.

The non-display area NDA may include a first non-display area NDA1 adjacent to the display area DA and a second non-display area NDA2 adjacent to the optical area OA. For example, the first non-display area NDA1 is located in an outer periphery of the display area DA and may enclose the display area DA. The second non-display area NDA2 is located in the display area DA and may enclose the optical area OA.

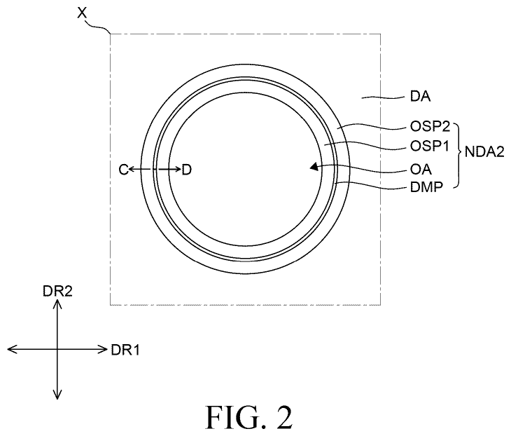

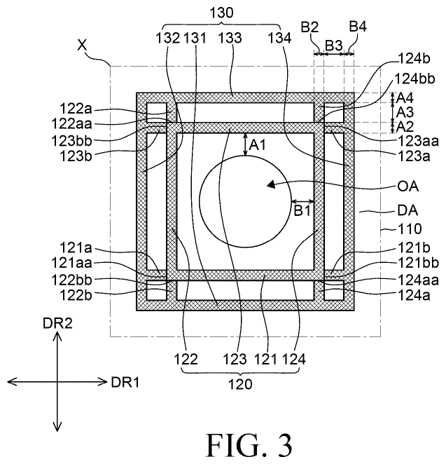

FIGS. 2 and 3 are enlarged plan views of an area X of FIG. 1 according to an exemplary embodiment of the present disclosure.

Referring to FIGS. 2 and 3, the second non-display area NDA2 may include an optical area OA, a first separation area OSP1 which encloses the optical area OA, a dam area DAM which encloses the first separation area OSP1, and a second separation area OSP2 which encloses the dam area DAM. The display area DA may be disposed so as to enclose the second separation area OSP2.

The optical area OA is a position in which a hole is formed in a display panel. The optical area OA having a hole is disposed in the display area DA to implement a slim bezel or a narrow bezel of the display device.

A back plate 110 which encloses the optical area OA may be disposed in a part of the second non-display area NDA2. The back plate 110 may not be disposed in the optical area OA. For example, in the optical area OA, the back plate 110 may include a hole.

In a part of the display area DA and a part of the second non-display area NDA2, a first reinforcement pattern 120 which is spaced apart from the optical area OA may be provided.

A planar shape of the first reinforcement pattern 120 may be a polygonal shape.

The first reinforcement pattern 120 may include a first part 121 extending in a first direction DR1, a second part 122 which extends in a second direction DR2 which is different from the first direction and is connected to an end 121aa of the first part 121, a third part 123 which extends in the first direction DR1 and is connected to an end 122aa of the second part 122, and a fourth part 124 which extends in the second direction DR2 and is connected to an end 123aa of the third part 123 and the other end 121bb of the first part 121.

A planar shape of the first reinforcement pattern 120 may be a closed curve shape. A planar shape of the first reinforcement pattern 120 may be a quadrangular shape, but the shape of the first reinforcement pattern 120 is not limited thereto.

The first reinforcement pattern 120 may be disposed to be spaced apart from the optical area OA.

The back plate 110 may be disposed between the first reinforcement pattern 120 and the optical area OA. By doing this, concentration of a stress on a partial area of the second non-display area NDA2 which encloses the optical area OA is suppressed to suppress generation of cracks. For example, even though an external force is applied to the display device 100 or a stress is applied to the periphery of the optical area OA due to the influence generated during the process of forming the display device 100, the first reinforcement pattern 120 may suppress the crack from being generated in the display device 100.

A distance A1 between the first part 121 and the third part 123 of the first reinforcement pattern 120 and the optical area OA may be equal to or smaller than a distance B1 between the second part 122 and the fourth part 124 of the first reinforcement pattern 120 and the optical area OA.

In the meantime, when a stress acting in the second direction DR2 of the display panel is larger than a stress acting in the first direction DR1, a distance A1 between the first part 121 and the third part 123 of the first reinforcement pattern 120 and the optical area OA may be smaller than a distance B1 between the second part 122 and the fourth part 124 of the first reinforcement pattern 120 and the optical area OA. The smaller the distance between the first reinforcement pattern 120 and the optical area OA, the larger the strength to withstand the stress applied to the display panel due to the influence of the first reinforcement pattern 120.

Accordingly, it may be designed so as not to cause the crack in the display panel by adjusting the distance between the first reinforcement pattern 120 and the optical area OA according to the direction.

Distances A1 and B1 of the first to fourth parts 121, 122, 123, and 124 of the first reinforcement pattern 120 and the optical area OA in the first and second directions DR1 and DR2 may be smaller than a width A2 of the first part 121 and a width A2 of the third part 123 in the second direction DR2 and a width B2 of the second part 122 and a width B2 of the fourth part 124 in the first direction DR1.

The optical area OA and the first reinforcement pattern 120 are disposed to be close so that the effect of the first reinforcement pattern 120 which reinforces the rigidity of the display panel in the peripheral area of the optical area OA may be increased.

A part of the display area DA and a part of the second non-display area NDA2 may include a plurality of extension reinforcement patterns 121a, 121b, 122a, 122b, 123a, 123b, 124a, and 124b extending from the first reinforcement pattern 120 in the first direction DR1 or in the second direction DR2 which is different from the first direction DR1.

The plurality of extension reinforcement patterns 121a, 121b, 122a, 122b, 123a, 123b, 124a, and 124b may extend from at least one part of the first part 121, the second part 122, the third part 123, and the fourth part 124 of the first reinforcement pattern 120.

For example, the plurality of extension reinforcement patterns 121a, 121b, 122a, 122b, 123a, 123b, 124a, and 124b may include a first extension reinforcement pattern 121a extending from one side 121aa of the first part 121, a second extension reinforcement pattern 121b extending from the other side 121bb of the first part 121, a third extension reinforcement pattern 122a extending from one side 122aa of the second part 122, a fourth extension reinforcement pattern 122b extending from the other side 122bb of the second part 122. Further, the plurality of extension reinforcement patterns 121a, 121b, 122a, 122b, 123a, 123b, 124a, and 124b may include a fifth extension reinforcement pattern 123a extending from one side 123aa of the third part 123, a sixth extension reinforcement pattern 123b extending from the other side 123bb of the third part 123, a seventh extension reinforcement pattern 124a extending from one side 124aa of the fourth part 124, and an eighth extension reinforcement pattern 124b extending from the other side 124bb of the fourth part 124.

The first to eighth extension reinforcement patterns 121a, 121b, 122a, 122b, 123a, 123b, 124a, and 124b extend from the first reinforcement pattern 120 to be integrally formed. By doing this, the rigidity of the peripheral area of the optical area OA may be improved.

The second reinforcement pattern 130 may be disposed so as to enclose the first reinforcement pattern 120 and the first to eighth extension reinforcement patterns 121a, 121b, 122a, 122b, 123a, 123b, 124a, and 124b.

A planar shape of the second reinforcement pattern 130 may be a polygonal shape.

For example, the second reinforcement pattern 130 may include a fifth part 131 extending in the first direction DR1, a sixth part 132 which extends in the second direction DR2 and is connected to an end 131aa of the fifth part 131, a seventh part 133 which extends in the first direction DR1 and is connected to an end 132aa of the sixth part 132, and an eighth part 134 which extends in the second direction DR2 and is connected to an end 133aa of the seventh part 133 and the other end 131bb of the fifth part 131.

The second reinforcement pattern 130 may be disposed so as to enclose the first reinforcement pattern 120 and the first to eighth extension reinforcement patterns 121a, 121b, 122a, 122b, 123a, 123b, 124a, and 124b, but the shape of the second reinforcement pattern 130 is not limited thereto.

The second reinforcement pattern 130 is disposed so as to enclose the first reinforcement pattern 120 and the first to eighth extension reinforcement patterns 121a, 121b, 122a, 122b, 123a, 123b, 124a, and 124b so that the reinforcement patterns which enclose the optical area OA may be formed with a closed curve shape. Therefore, even though the stress is applied in all directions, the crack may be suppressed.

Further, even though in FIG. 3, one quadrangular second reinforcement pattern 130 has been illustrated, the number of second reinforcement patterns 130 is not limited thereto and two or more second reinforcement patterns 130 may be provided.

The second reinforcement pattern 130 may be spaced apart from at least one of the first part 121, the second part 122, the third part 123, and the fourth part 124 of the first reinforcement pattern 120.

For example, as illustrated in FIG. 3, the second reinforcement pattern 130 may be spaced apart from all the first part 121, the second part 122, the third part 123, and the fourth part 124 of the first reinforcement pattern 120.

The back plate 110 and the first to eighth extension reinforcement patterns 121a, 121b, 122a, 122b, 123a, 123b, 124a, and 124b may be disposed between the second reinforcement pattern 130 and the first reinforcement pattern 120.

The second reinforcement pattern 130 may be connected to at least one extension reinforcement pattern of the first to eighth extension reinforcement patterns 121a, 121b, 122a, 122b, 123a, 123b, 124a, and 124b.

Each part of the second reinforcement pattern 130 may be connected to at least two extension reinforcement patterns. For example, the fifth part 131 of the second reinforcement pattern 130 may be connected to the fourth and seventh extension reinforcement patterns 122b and 124a and the sixth part 132 of the second reinforcement pattern 130 may be connected to the first and sixth extension reinforcement patterns 121a and 123b. The seventh part 133 of the second reinforcement pattern 130 may be connected to the third and eighth extension reinforcement patterns 122a and 124b and the eighth part 134 of the second reinforcement pattern 130 may be connected to the second and fifth extension reinforcement patterns 121b and 123a.

As described above, the back plate 110, the first reinforcement pattern 120, the plurality of extension reinforcement patterns 121a, 121b, 122a, 122b, 123a, 123b, 124a, and 124b, and the second reinforcement pattern 130 are disposed in the vicinity of the optical area OA. Therefore, even during the process of forming the optical area OA, the crack due to the stress applied to the display panel may not be generated.

Specifically, the plurality of extension reinforcement patterns 121a, 121b, 122a, 122b, 123a, 123b, 124a, and 124b is connected to the first reinforcement pattern 120 and the second reinforcement pattern 130 is connected to the plurality of extension reinforcement patterns 121a, 121b, 122a, 122b, 123a, 123b, 124a, and 124b. The rigidity of the display panel is ensured in a specific direction (for example, the second direction) in which a large stress is applied.

The distances A3 and B3 between the first reinforcement pattern 120 and the second reinforcement pattern 130 in the first and second direction DR1 and DR2 may be larger than widths A2 and B2 of the first reinforcement pattern 120 and widths A4 and B4 of the second reinforcement pattern 130 in the first and second directions DR1 and DR2.

Therefore, the plurality of extension reinforcement patterns 121a, 121b, 122a, 122b, 123a, 123b, 124a, and 124b may be disposed between the first reinforcement pattern 120 and the second reinforcement pattern 130.

The widths A4 and B4 of the second reinforcement pattern 130 in the first and second directions DR1 and DR2 may be larger than the widths A2 and B2 of the first reinforcement pattern 120 in the first and second directions DR1 and DR2. Alternatively, the widths A4 and B4 of the second reinforcement pattern 130 in the first and second directions DR1 and DR2 may be larger than the widths of the plurality of extension reinforcement patterns 121a, 121b, 122a, 122b, 123a, 123b, 124a, and 124b in the first and second directions DR1 and DR2.

The widths A4 and B4 of the second reinforcement pattern 130 which encloses the first reinforcement pattern 120 and the plurality of extension reinforcement patterns 121a, 121b, 122a, 122b, 123a, 123b, 124a, and 124b are larger than the widths A2 and B2 of the first reinforcement pattern 120 or the widths of the plurality of extension reinforcement patterns 121a, 121b, 122a, 122b, 123a, 123b, 124a, and 124b. Accordingly, the rigidity of the display panel located in the peripheral area of the optical area OA may be improved.

Widths A2 and A4 in the second direction of a part of the first reinforcement pattern 120 and a part of the second reinforcement pattern 130 extending in the first direction DR1 may be larger than widths B2 and B4 in the first direction of a part of the first reinforcement pattern 120 and a part of the second reinforcement pattern 130 extending in the second direction DR2. Accordingly, the rigidity of the display panel may be ensured also in a specific direction (for example, the second direction) in which a large stress is applied.

In the meantime, in FIG. 3, a structure in which the planar shape of the second reinforcement pattern 130 is a quadrangular shape and eight extension reinforcement patterns are provided has been illustrated, but the present disclosure is not limited thereto.

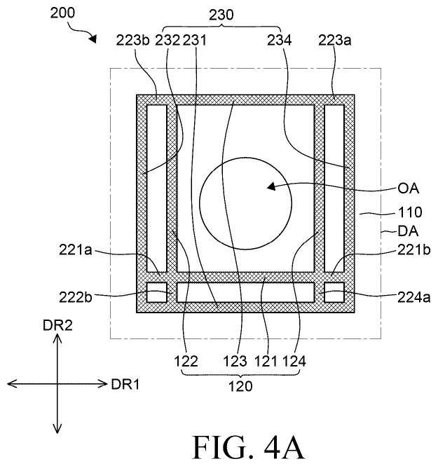

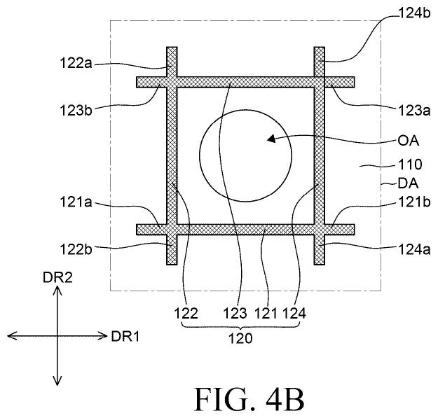

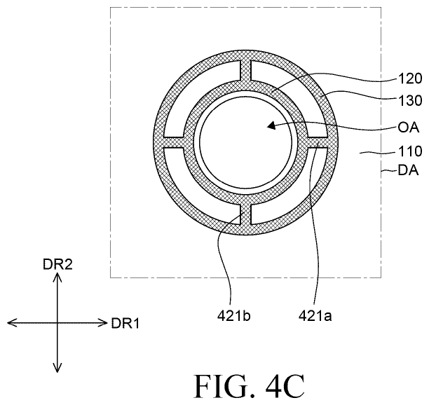

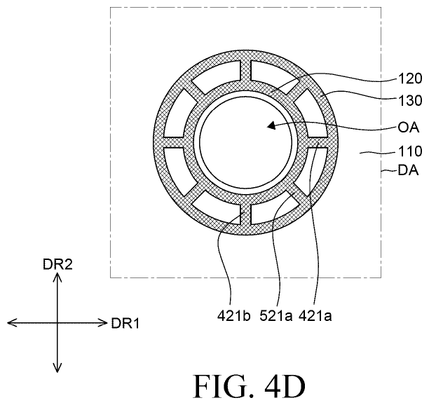

A structure of the second reinforcement pattern 130 and the plurality of extension reinforcement patterns will be reviewed as below with reference to FIG. 4 as an example.

FIGS. 4A to 4D are views illustrating various structures of a reinforcement pattern of the present disclosure.

Referring to FIGS. 4A to 4D, the reinforcement patterns may have a structure including a first reinforcement pattern 120 having a closed curve line as a planar shape and a plurality of extension reinforcement patterns extending from the first reinforcement pattern 120 in the first direction and the second direction which is different from the first direction.

Specifically, referring to FIG. 4A, a display device 200 according to another exemplary embodiment of the present disclosure may include a back plate 110 which encloses an optical area OA and a plurality of reinforcement patterns. The plurality of reinforcement patterns may include a first reinforcement pattern 120, a plurality of extension reinforcement patterns 221a, 221b, 222b, 223a, 223b, and 224b, and a second reinforcement pattern 230. The display device has the same structure as the display device illustrated in FIG. 3 except that the plurality of extension reinforcement patterns 221a, 221b, 222b, 223a, 223b, and 224b extends from only one part of the first reinforcement pattern 120 and the second reinforcement pattern 230 is configured by three sides on the plane. Therefore, a redundant description will be omitted.

The plurality of extension reinforcement patterns 221a, 221b, 222b, 223a, 223b, and 224b may include a first extension reinforcement pattern 221a and a second extension reinforcement pattern 221b extending from a first part 121 of the first reinforcement pattern 120 in the first direction DR1, a fourth extension reinforcement pattern 222b extending from a second part 122 of the first reinforcement pattern 120 in the second direction DR2, a fifth extension reinforcement pattern 223a and a sixth extension reinforcement pattern 223b extending from a third part 123 of the first reinforcement pattern 120 in the first direction DR1, and a seventh extension reinforcement pattern 224a extending from a fourth part 124 of the first reinforcement pattern 120 in the second direction DR2.

The second reinforcement pattern 230 may include a fifth part 231 extending in the first direction DR1, a sixth part 232 which is connected to one end of the fifth part 231 and extends in the second direction DR2, and an eighth part 234 which is connected to the other end of the fifth part 231 and extends in the second direction DR2.

The fifth part 231 of the second reinforcement pattern 230 may be directly connected to the first and second extension reinforcement patterns 221a and 221b.

One end of the sixth part 232 of the second reinforcement pattern 230 is directly connected to the sixth extension reinforcement pattern 223b and one end of the eighth part 234 of the second reinforcement pattern 230 may be directly connected to the fifth extension reinforcement pattern 233a. Therefore, the second reinforcement pattern 230, the third part 123 of the reinforcement pattern 120, the fifth extension reinforcement pattern 223a, and the sixth extension reinforcement pattern 223b may enclose outermost peripheries of a plurality of remaining reinforcement patterns.

The second reinforcement pattern 230, the third part 123 of the first reinforcement pattern 120, the fifth extension reinforcement pattern 223a, and the sixth extension reinforcement pattern 223b are connected to each other to form a closed curve line. The closed curve line formed by the second reinforcement pattern 230, the third part 123 of the first reinforcement pattern 120, the fifth extension reinforcement pattern 223a, and the sixth extension reinforcement pattern 223b which are connected to each other may have a shape having at least one corner. Therefore, even though the stress is applied in all directions, the crack may be suppressed.

Referring to FIG. 4B, the first reinforcement pattern 120 may include a first part 121 extending in the first direction DR1, a second part 122 which extends in the second direction DR2 and is connected to one end of the first part 121, a third part 123 which extends in the first direction DR1 and is connected to one end of the second part 122, and a fourth part which extends in the second direction DR2 and is connected to one end of the third part 123 and the other end of the first part 121.

Further, the first and second extension reinforcement patterns 121a and 121b are connected to the first part 121 of the first reinforcement pattern 120 and the third and fourth extension reinforcement patterns 122a and 122b are connected to the second part 122 of the first reinforcement pattern 120. The fifth and sixth extension reinforcement patterns 123a and 123b are connected to the third part 123 of the first reinforcement pattern 120 and the seventh and eighth extension reinforcement patterns 124a and 124b may be connected to the fourth part 124 of the first reinforcement pattern 120.

The first reinforcement pattern 120 is formed to have a closed curve line and the plurality of extension reinforcement patterns 121a, 121b, 122a, 122b, 123a, 123b, 124a, and 124b may be connected to the first reinforcement pattern 120.

Referring to FIG. 4C, a first reinforcement pattern 120 having a circular shape on the plane may be disposed so as to enclose the optical area OA. The back plate 110 may be disposed between the first reinforcement pattern 120 and the optical area OA.

A plurality of extension reinforcement patterns 421a and 421b may be connected to the first reinforcement pattern 120. For example, the plurality of extension reinforcement patterns 421a is connected to the first reinforcement pattern 120 in the first direction DR1 and the plurality of extension reinforcement patterns 421b may be connected to the first reinforcement pattern 120 in the second direction DR2.

A second reinforcement pattern 130 which encloses the first reinforcement pattern 120 and the plurality of extension reinforcement patterns 421a and 421b may be disposed.

The second reinforcement pattern 130 may be connected to the plurality of extension reinforcement patterns 421a and 421b.

A planar shape of the second reinforcement pattern 130 may be a circular shape. Therefore, the first reinforcement pattern 120, the plurality of extension reinforcement patterns 421a and 421b, and the second reinforcement pattern 130 may be formed with a closed curve shape as a whole.

Referring to FIG. 4D, in the structure of FIG. 4C, at least one additional extension reinforcement pattern 521a extending in a direction between the first direction DR1 and the second direction DR2 may be further included.

The plurality of extension reinforcement patterns 421a and 421b and the additional extension reinforcement pattern 521a may be connected to the second reinforcement pattern 130.

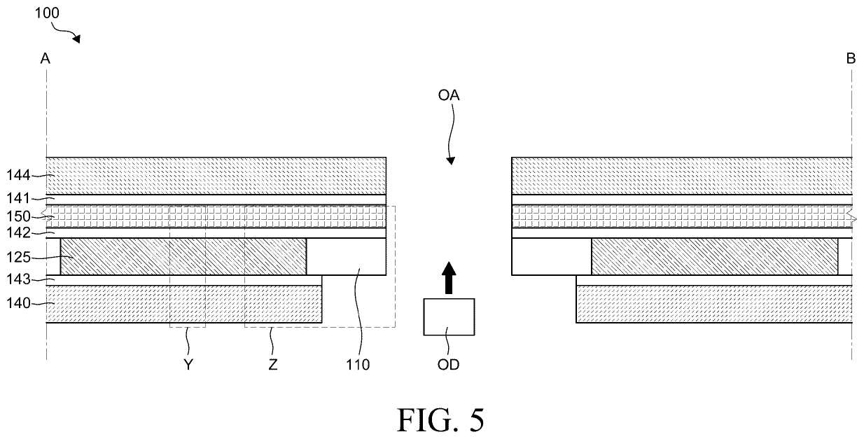

FIG. 5 is a cross-sectional view taken along a line A-B of FIG. 1 according to an exemplary embodiment of the present disclosure.

Referring to FIG. 5, the display device 100 may include a back plate 110, a plurality of reinforcement patterns 125, an additional plate 140, a display panel 150, a polarization layer 144, and an optical device OD.

Specifically, a hole may be provided in the optical area OA of the display device 100. In the optical area OA, the back plate 110, the plurality of reinforcement patterns 125, the additional plate 140, the display panel 150, and the polarization layer 144 may not be disposed. In the optical area OA, at least one optical device OD may be disposed.

The polarization layer 144 may be disposed above the display panel 150 of the display device 100. The polarization layer 144 may be attached to a top surface of the display panel 150 by means of a first adhesive layer 141, but is not limited thereto.

The back plate 110 and the plurality of reinforcement patterns 125 may be disposed below the display panel 150.

The back plate 110 and the plurality of reinforcement patterns 125 may be connected to a lower portion of the display panel 150 by means of a second adhesive layer 142, but the present disclosure is not limited thereto.

The back plate 110 may serve to support the display panel 150. The plurality of reinforcement patterns 125 may include a first reinforcement pattern, a plurality of extension reinforcement patterns, and a second reinforcement pattern illustrated in FIG. 3 or FIG. 4. The plurality of reinforcement patterns 125 is located in the vicinity of the optical area OA to suppress cracks from generating in the back plate 110 and the display panel 150 disposed above the back plate 110.

The back plate 110 and the plurality of reinforcement patterns 125 may be disposed on the same layer. The back plate 110 and the plurality of reinforcement patterns 125 have the same thickness, but are not limited thereto. As the back plate 110 and the plurality of reinforcement patterns 125 are disposed on the same layer, the rigidity of the display device 100 is increased and a display device with a small thickness may be implemented.

Specifically, the back plate 110 and the plurality of reinforcement patterns 125 are disposed on the same layer and enclose the optical area OA. Therefore, during the process of forming the optical area OA, the plurality of reinforcement patterns 125 may be suppressed from being thermally affected.

The back plate 110 and the plurality of reinforcement patterns 125 may include different materials. For example, the back plate 110 may include polyethylene terephthalate (PET), polyimide (PI), or polycarbonate (PC), but is not limited thereto. The plurality of reinforcement patterns 125 may include metal or graphite.

A strength of the plurality of reinforcement patterns 125 may be larger than a strength of the back plate 110. Accordingly, the plurality of reinforcement patterns 125 may increase the strength of the display device 100 also in the vicinity of the optical area OA.

An elastic modulus of the plurality of reinforcement patterns 125 may be 26,000 Mpa to 220,000 Mpa. A Poisson's ratio of the plurality of reinforcement patterns 125 may be 0.2 to 0.3.

An elastic modulus of the back plate 110 may be 4,000 Mpa to 5,000 Mpa. A Poisson's ratio of the back plate 110 is 0.27 to 0.29.

The additional plate 140 may be disposed below the back plate 110 and the plurality of reinforcement patterns 125. The additional plate 140 may be attached to lower portions of the back plate 110 and the plurality of reinforcement patterns 125 by means of a third adhesive layer 143, but is not limited thereto.

The additional plate 140 may include metal. In this case, the additional plate 140 and the third adhesive layer 143 may be disposed so as to expose a part of one surface of the back plate 110 in an area adjacent to the optical area OA.

The additional plate 140 serves to support configurations disposed above the additional plate 140 or relieve or absorb impacts applied to the display device 100.

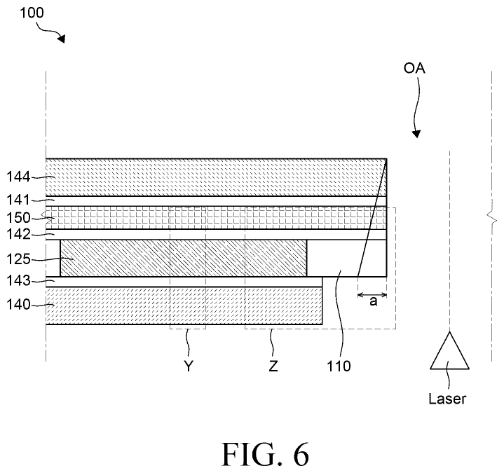

FIG. 6 is a view simply illustrating a process of forming an optical area in a display device according to an exemplary embodiment of the present disclosure.

In order to form an optical area OA in the display device 100, a process of irradiating a partial area of a rear surface of the display device 100 with laser may be used. By doing this, holes may be formed in the back plate 110, the plurality of reinforcement patterns 125, the display panel 150, and the polarization layer 144. An area corresponding to the holes formed in the back plate 110, the plurality of reinforcement patterns 125, the display panel 150, and the polarization layer 144 may be an optical area OA.

The optical area OA may not overlap (e.g., non-overlapping) the back plate 110, the plurality of reinforcement patterns 125, the additional plate 140, the display panel 150, and the polarization layer 144.

In the meantime, during the process of irradiating the display device 100 with laser, a thermally affected area a may be generated in a partial area of the display device 100.

The closer to the laser, the larger the thermally affected area a. For example, a thermally affected area a of the back plate 110 located to be close to the laser may be larger than a thermally affected area a of the display panel 150.

In the thermally affected area a generated by the laser process, a stress is applied to the back plate 110 and the display panel 150 and in an area in which a large stress is applied, cracks may be generated.

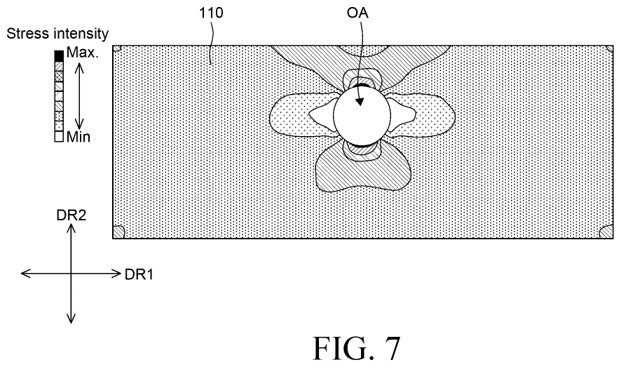

FIG. 7 is a view illustrating a stress applied to a back plate in a peripheral area of an optical area according to an exemplary embodiment of the present disclosure.

When a tensile stress of approximately 2 MPa is applied to one side and the other side of the back plate 110 in the second direction DR2, a stress generated in the optical area OA is illustrated. The tensile stress of 2 MPa is applied for one second.

Referring to FIG. 7, it is understood that when a reinforcement pattern is not disposed in the vicinity of the optical area OA, the tensile stress is applied to the back plate 110 in the first direction DR1 and the second direction DR2.

Specifically, it is understood that the tensile stress applied to the back plate 110 in the second direction DR2 is larger than the tensile stress applied to the back plate 110 in the first direction DR1. A maximum value of the tensile stress applied to the back plate 110 in the second direction DR2 is 71.7 MPa.

As illustrated in FIG. 7, when the plurality of reinforcement patterns 125 is not disposed in the vicinity of the optical area OA, the back plate 110 may be damaged.

The display device according to the exemplary embodiment of the present disclosure includes a plurality of reinforcement patterns 125 disposed on the same layer as the back plate 110 so that even though the stress is applied to the back plate 110, the crack may be suppressed.

Further, when the stress which is applied to the back plate 110 in a specific direction (for example, the second direction) is large so that the reinforcement pattern is disposed only in a specific direction, the stress may spread in the other direction. Therefore, the first reinforcement pattern, the plurality of extension reinforcement patterns, and the second reinforcement pattern are connected to each other to have a closed curve shape. Therefore, even though the stress spreads not in a specific direction, but in the other direction, the damage generated in the back plate 110 and the display panel 150 attached with the back plate 110 may be suppressed.

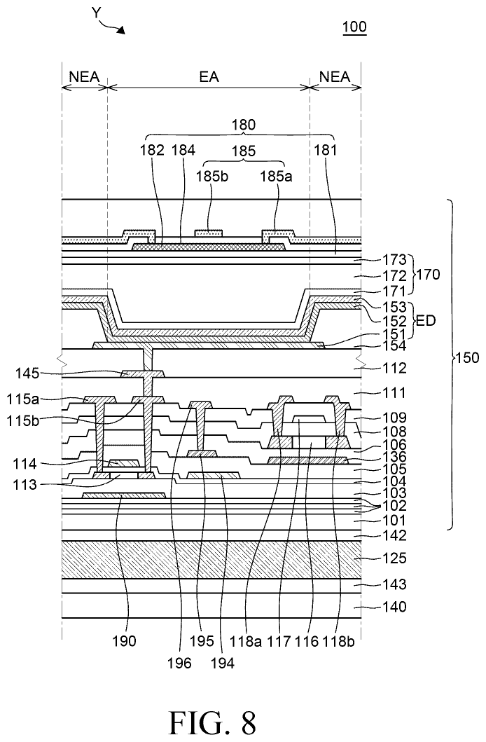

FIG. 8 is a cross-sectional view of an area Y of FIG. 5 according to an exemplary embodiment of the present disclosure.

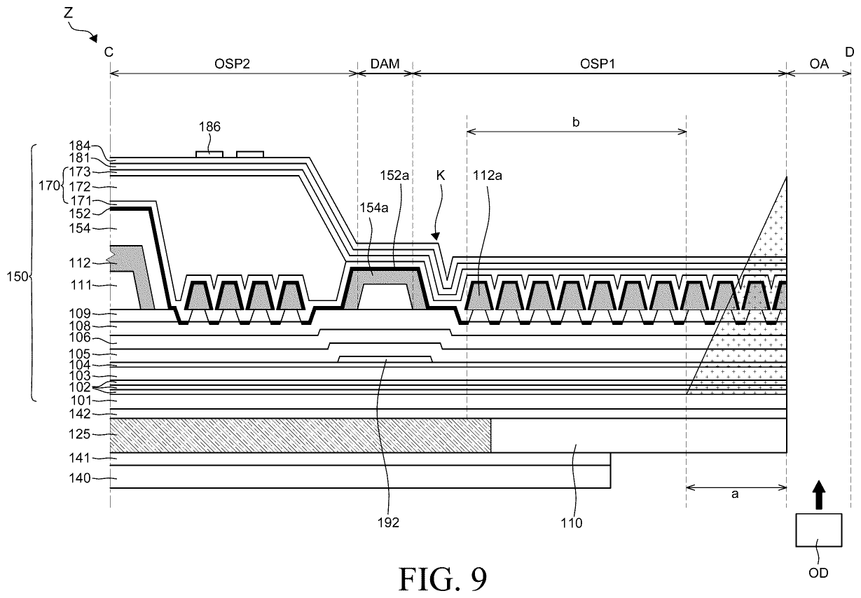

FIG. 9 is a cross-sectional view of an area Z of FIG. 5 according to an exemplary embodiment of the present disclosure.

The area Y is an area including a display area DA of the display device 100 and the area Z is an area including the second non-display area NDA2.

Referring to FIGS. 8 and 9, the display area DA of the display device 100 may include an emission area EA and a non-emission area NEA. In the emission area EA, a light emitting diode ED and at least one transistor may be disposed and in the non-emission area NEA, a plurality of transistors and a plurality of signal lines may be disposed.

In at least a part of the display area DA, the plurality of reinforcement patterns 125 may be disposed so as to overlap the emission area EA and the non-emission area NEA. The plurality of reinforcement patterns 125 may include a first reinforcement pattern, a plurality of extension reinforcement patterns, and a second reinforcement pattern illustrated in FIGS. 3 and 4.

In at least a part of the display area DA, the plurality of reinforcement patterns 125 may be disposed on a rear surface of the display panel 150. The plurality of reinforcement patterns 125 may be attached to a rear surface of the display panel 150 by means of the second adhesive layer 142. The additional plate 140 may be attached to the rear surface of the plurality of reinforcement patterns 125 by means of a third adhesive layer 143 and in some cases, the additional plate 140 may not overlap the emission area EA in the display area DA.

The substrate 101 of the display panel 150 may be disposed on the second adhesive layer 142. A plurality of transistors, a light emitting diode ED, an encapsulation layer 170, and a touch layer 180 may be included on the substrate 101.

Specifically, a buffer layer 102 may be disposed on the substrate 101. The buffer layer 102 may minimize or delay the diffusion of moisture or oxygen which permeates the substrate 101. The buffer layer 102 may be formed by alternately laminating silicon nitride (SiNx) and silicon oxide (SiOx) at least once, but is not limited thereto.

A first light shielding layer 190 may be disposed on the buffer layer 102. The first light shielding layer 190 may suppress light from passing through a first active layer 113 of a first thin film transistor. For example, the first active layer 113 may be disposed so as to overlap the first light shielding layer 190.

A first insulating layer 103 may be disposed on the first light shielding layer 190.

The first thin film transistor may be disposed on the first insulating layer 103. The first thin film transistor may include the first active layer 113, a first gate electrode 114, a first source electrode 115a, and a first drain electrode 115b.

The first active layer 113 may be disposed on the first insulating layer 103. The first active layer 113 includes metal oxide semiconductor, such as indium gallium zinc oxide (IGZO) or a silicon based semiconductor material, such as amorphous silicon or polycrystalline silicon, but is not limited thereto. The first active layer 113 may include a channel region, a source region, and a drain region.

A second insulating layer 104 may be disposed on the first active layer 113.

The first gate electrode 114 may be disposed on the second insulating layer 104. The first gate electrode 114 may be disposed on the second insulating layer 104 so as to overlap the channel region of the first active layer 113.

A third insulating layer 105 may be disposed on the first gate electrode 114.

The first source electrode 115a and the first drain electrode 124 may be disposed on the third insulating layer 105.

The first source electrode 115a and the first drain electrode 115b may be electrically connected to the first active layer 113 through a contact hole. The first source electrode 115a and the first drain electrode 115b may be formed of a metal material.

A storage electrode may be disposed to be spaced apart from the first thin film transistor 120. The storage electrode may include a first storage electrode 194, a second storage electrode 195, and a third storage electrode 196.

The second storage electrode 195 may be disposed on the first storage electrode 194. The second storage electrode 195 may be disposed on the third insulating layer 105 and a capacitance may be formed with the third insulating layer 105 between the first storage electrode 194 and the second storage electrode 195 as a dielectric material.

A second thin film transistor may be disposed so as to be spaced apart from the first thin film transistor and the storage electrode. The second thin film transistor may include a second source electrode 118a, a second gate electrode 117, a second active layer 116, and a second drain electrode 118b.

A second light shielding layer 136 may be disposed on the same layer as the second storage electrode 195.

The second light shielding layer 136 may suppress light which is directed to the second active layer 116, similar to the first light shielding layer 190, to extend the lifespan of the second thin film transistor 130. For example, the second active layer 116 may be disposed so as to overlap the second light shielding layer 136.

A fourth insulating layer 106 may be disposed on the second light shielding layer 136.

The second active layer 116 may be disposed on the fourth insulating layer 106. The second active layer 116 may include a source region, a drain region, and a channel region between the source region and the drain region.

The second active layer 116 includes metal oxide semiconductor, such as indium gallium zinc oxide (IGZO) or a silicon based semiconductor material, such as amorphous silicon or polycrystalline silicon, but is not limited thereto.

A fifth insulating layer 108 may be disposed on the second active layer 116.

The second gate electrode 117 may be disposed on the fifth insulating layer 108.

The second gate electrode 117 may be formed of the same material as the first gate electrode 114.

A sixth insulating layer 109 may be disposed on the second gate electrode 117.

A first source electrode 115a, a first drain electrode 115b, a second storage electrode 196, a second source electrode 118a, and a second drain electrode 118b may be disposed on the sixth insulating layer 109.

A first protection layer 111 may be disposed on the first source electrode 115a and the first drain electrode 115b. The first protection layer 111 planarizes an upper portion of the first thin film transistor 120 and may protect the first thin film transistor 120. The first protection layer 111 may be formed of an organic material.

A second protection layer 112 may be disposed on the first protection layer 111.

A connection electrode 145 may be disposed between the first protection layer 111 and the second protection layer 112. The connection electrode 145 may electrically connect the first thin film transistor 120 and an emission unit 150.

The light emitting diode ED may be disposed on the second protection layer 112. The light emitting diode ED may include a first electrode 151, an organic layer 152, and a second electrode 153.

The first electrode 151 may be disposed on the second protection layer 112. The first electrode 151 may be electrically connected to the first thin film transistor through a contact hole formed in the second protection layer 112. The first electrode 151 may include a reflection electrode which reflects light, but is not limited thereto.

The organic layer 152 may be disposed on the first electrode 151. The organic layer 152 may include at least one emission layer, but is not limited thereto.

The second electrode 153 may be disposed on the organic layer 152. The second electrode 153 may be an electrode which transmits light, but is not limited thereto.

A bank 154 may be disposed so as to expose the first electrode 151. The bank 154 defines an emission area EA of a sub pixel disposed in the display area DA and may be disposed so as to cover an edge portion of the first electrode 151.

The encapsulation layer 170 may be disposed on the bank 154 or the light emitting diode ED. The encapsulation layer 170 may include one or more insulating layers. For example, the encapsulation layer 170 may include a first encapsulation layer 171, a second encapsulation layer 172 on the first encapsulation layer 171, and a third encapsulation layer 173 on the second encapsulation layer 172.

The encapsulation layer 170 may include one or more inorganic layers and one or more organic layers. For example, each of the first encapsulation layer 171 and the third encapsulation layer 173 includes one or more inorganic layers and the second encapsulation layer 172 may include one or more organic layers.

A touch buffer layer 181 may be disposed on the encapsulation layer 170. For example, the touch buffer layer 181 may be disposed on the third encapsulation layer 173.

A touch insulating layer 184 may be disposed on the touch buffer layer 181.

A first touch electrode 185a and a second touch electrode 185b may be disposed on the touch insulating layer 184.

A third touch electrode 182 may be disposed between the touch buffer layer 181 and the touch insulating layer 184. The third touch electrode 182 may be electrically connected to the first touch electrode 185a through a contact hole formed in the touch insulating layer 184.

In the meantime, even though in FIG. 8, a structure in which first to third touch electrodes 185a, 185b, and 182 overlap a part of the emission area EA and a part of the non-emission area NEA is illustrated, the present disclosure is not limited thereto. For example, the first to third touch electrodes 185a, 185b, and 182 overlap a part of the non-emission area NEA, but do not overlap the emission area EA.

In the display area DA, a part of the plurality of reinforcement patterns 125 may overlap at least one touch electrode. For example, the plurality of reinforcement patterns 125 may overlap at least one of the first to third touch electrodes 185a, 185b, and 182.

The display panel 150 may include an optical area OA, a first separation area OSP1, a dam area DAM, and a second separation area OSP2 in the second non-display area NDA2.

In the optical area OA, an optical device OD may be disposed.

The first separation area OSP1 may be adjacent to the optical area OA. In the first separation area OSP1, the display panel 150, the back plate 110, the plurality of reinforcement patterns 125, and the additional plate 140 may be disposed.

The dam area DAM may be adjacent to the first separation area OSP1. In the dam area DAM, the display panel 150, the plurality of reinforcement patterns 125, and the additional plate 140 may be disposed.

The second separation area OSP2 may be adjacent to the dam area DAM. In the second separation area OSP2, the display panel 150, the plurality of reinforcement patterns 125, and the additional plate 140 may be disposed and in some cases, the back plate 110 may be further disposed.

A part (for example, a thermally affected area) of the first separation area OSP1 may be affected from the outside during the process of forming the optical area OA.

The thermally affected area a may be present in a partial area between the optical area OA and the dam area DAM. Further, the thermally affected area a may be disposed between the optical area OA and a sub dam 112a, among a plurality of sub dams 112a disposed in the first separation area OSP1, which is second close to the dam 154a.

In the thermally affected area a, the plurality of reinforcement patterns 125 may not be disposed. Further, for the sake of the reliability of the plurality of reinforcement patterns 125, the plurality of reinforcement patterns 125 may not be disposed in a margin area b which is spaced apart from the thermally affected area a by a predetermined distance. Here, the margin area b may include an area in which two or more patterns 112a are disposed, from the thermally affected area a.

For example, the plurality of reinforcement patterns 125 is not disposed between the optical area OA and a sub dam 112a, among a plurality of sub dams 112a disposed in the first separation area OSP1, which is second close to the dam 154a.

When the plurality of reinforcement patterns 125 is disposed in the thermally affected area a, the plurality of reinforcement patterns 125 may be deformed by the heat.

When the plurality of reinforcement patterns 125 is disposed in the first separation area OSP1, the plurality of reinforcement patterns may be disposed between the sub dam 112a second closer to the dam 154a and the dam area DAM.

Specifically, the plurality of reinforcement patterns 125 may overlap an area K between a sub dam 112a which is the closest to the dam 154a and the dam area DAM. In the area K between a sub dam 112a which is the closest to the dam 154a and the dam area DAM, the crack of the display panel 150 may occur due to the external influence in the plurality of reinforcement patterns 125. Therefore, the plurality of reinforcement patterns 125 overlaps the area K between a sub dam 112a which is the closest to the dam 154a and the dam area DAM to suppress the damage of the display panel 150.

The plurality of reinforcement patterns 125 may be disposed to extend to the dam area DAM, the second separation area OSP2, and a part of the display area DA.

In the first separation area OSP1, the plurality of sub dams 112a and the plurality of insulating layers may be disposed on the substrate 101 of the display panel 150.

In the dam area DAM, at least one dam DAM, at least one metal layer 192, and a plurality of insulating layers may be disposed on the substrate 101 of the display panel 150.

In the second separation area OSP2, the plurality of sub dams 112a, at least one hole crack detection unit 186, and the plurality of insulating layers may be disposed on the substrate 101 of the display panel 150.

During the process of forming the optical area OA, an end portion of the organic layer 152a disposed in the first separation area OSP1 may be exposed.

The organic layer 152a may be formed of the same material as the organic layer 152 of the light emitting diode ED disposed in the display area DA and may be formed on the same layer as the organic layer 152.

Accordingly, a moisture permeation path may be formed from an end portion of the organic layer 152a exposed through the optical area OA to the light emitting diode ED of the display area DA. In each of the first separation area OSP1, the dam area DAM, and the second separation area OSP2, a disconnected structure of the organic layer 152a is provided to block moisture, oxygen, and foreign materials which may move along the moisture permeation path.

The dam 154a disposed in the dam area DAM may be formed of the same material as the second protection layer 112 and the bank 154. In order to reduce the area of the second non-display area NDA2, one dam 154a may be disposed, but the present disclosure is not limited thereto.

Further, the organic layer 152a may be disposed so as to cover the dam 154a. The dam 154a increases a permeation path of moisture and oxygen to more effectively suppress the permeation of moisture and oxygen.

In order to suppress the damage of the display panel 150 due to moisture and oxygen which enters through the end portion of the exposed organic layer 152a from the outside, a plurality of sub dams 112a may be disposed in each of the first separation area OSP1 and the second separation area OSP2.

The touch buffer layer 181 may be disposed across the display area DA and the second non-display area NDA2. For example, the touch buffer layer 181 may be disposed across the first separation area OSP1, the dam area DMP, and the second separation area OSP2.

The hole crack detection unit 186 may be disposed on the touch buffer layer 181. For example, the hole crack detection unit 186 may be disposed in the second non-display area NDA2. For example, the hole crack detection unit 186 may be disposed in the second separation area OSP2, but is not limited thereto.

The optical area OA may be provided in a partial area of the display device 100. The optical area OA may be an area corresponding to the hole provided in the partial area of the display device 100.

Due to the process of forming the optical area OA or the hole formed in the optical area OA, configurations included in the display panel 150 or the back plate 110 disposed on the rear surface of the display panel 150 may be exposed to physical damage or chemical damage. For example, the display panel 150 or the back plate 110 may have a crack at the boundary of the optical area OA.

When the hole crack detection unit 186 is disconnected due to the crack, the hole crack detection unit 186 may not transmit an electrical signal to detect the crack.

The hole crack detection unit 186 may be disposed on the same layer as the first touch electrode 185 and may be disposed so as to enclose the optical area OA.

At least two hole crack detection units 186 may be disposed on the same layer as the first touch electrode 185, but are not limited thereto. The hole crack detection unit 186 may be disposed in the second separation area OSP2. For example, the hole crack detection unit 186 is disposed between the display area DA and the dam 154a.

The fourth metal layer 192 may be disposed in an area overlapping the dam 154a. The fourth metal layer 192 is disposed on the same layer as the first gate electrode 122 or formed of the same material. The fourth metal layer 192 may be an alignment mark required for the process of forming the optical area OA, but is not limited thereto.

A plurality of sub dams 112a may be disposed on the fifth insulating layer 108 and the sixth insulating layer 109. The plurality of sub dams 112a are spaced apart from each other. The plurality of sub dams 112a is disposed on the same layer as the second protection layer 112.

The first separation area OSP1 and the second separation area OSP2 may include an area in which the sixth insulating layer 109 is disposed and an area in which the sixth insulating layer 109 is not disposed. In the first separation area OSP1 and the second separation area OSP2, the plurality of sub dams 112a may be disposed on the sixth insulating layer 109.

The organic layer 152a may be disconnected by the plurality of sub dams 112a in the first separation area OSP1 and the second separation area OSP2. Therefore, the organic layer 152a may be disposed on top surfaces of the plurality of sub dams 112a and a top surface of the fifth insulating layer 108 in the first separation area OSP1 and the second separation area OSP2.

The organic layers 152a disposed on the top surfaces of the plurality of sub dams 112a and the top surface of the fifth insulating layer 108 may be spaced apart from each other. Accordingly, moisture and oxygen entering through the optical area OA from the outside may not be transmitted to the display area DA along the organic layer 152a so that the damage of the light emitting diode ED disposed in the display area DA may be suppressed. As a result, the lifespan of the light emitting diode ED may be increased so that the display device 100 may be driven with a low power.

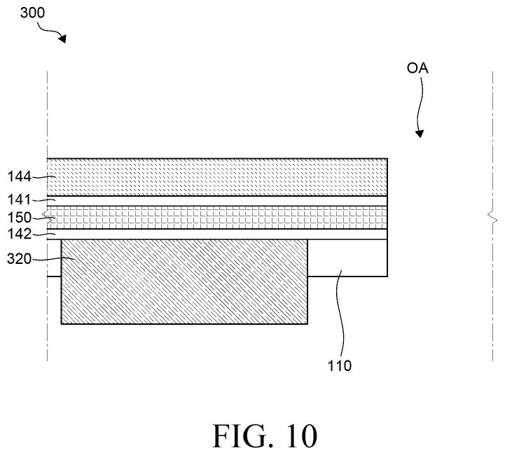

FIG. 10 is a cross-sectional view of a part of a display device according to another exemplary embodiment of the present disclosure.

Referring to FIG. 10, a display device 300 according to still another exemplary embodiment of the present disclosure may include a back plate 110, a reinforcement pattern 320, a display panel 150, and a polarization layer 144. Except that in at least a partial area of the display device 300, a reinforcement pattern 320 and an additional plate are integrally formed without providing a third adhesive layer, the display device 300 has the same structure as the display device illustrated in FIG. 5 so that a redundant description will be omitted.

The reinforcement pattern 320 may include a first reinforcement pattern, a plurality of extension reinforcement patterns, and a second reinforcement pattern illustrated in FIGS. 3 and 4.

The reinforcement pattern 320 may be disposed on the same layer as the back plate 110. At this time, a height of the reinforcement pattern 320 is higher than a height of the back plate 110. As the height of the reinforcement pattern 320 may be formed to be higher than a height of the back plate 110 in at least a partial area of the display device 300, the reinforcement pattern 320 supports a configuration disposed above the reinforcement pattern 320 and relieves and absorbs an impact applied to the display device 300.

That is, the reinforcement pattern 320 also serves as an additional plate to remove the configuration of the third adhesive layer and the additional plate. Accordingly, the structure of the display device 300 is simplified and the process is optimized to implement a unit-material.

The reinforcement pattern 320 may include a metal and in this case, the partial area of the back plate 110 may be disposed between the optical area OA and the reinforcement pattern 325.

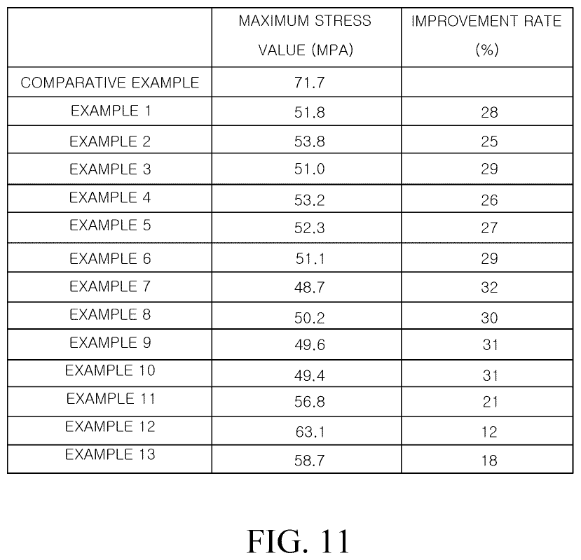

FIG. 11 is a view illustrating a stress applied to a back plate in a peripheral area of an optical area of display devices according to Comparative Example and Examples and an improvement rate.

When a tensile stress of approximately 2 MPa is applied to one side and the other side of the back plate of the display device in the second direction DR2, a stress generated in the optical area OA is illustrated. The tensile stress of 2 MPa is applied for one second.

A back plate of a display device according to Comparative Example has a structure illustrated in FIG. 7. A maximum value of the tensile stress applied to the back plate of Comparative Example in the second direction DR2 is 71.7 MPa.

In a display device 100 according to Example 1, a back plate 110 includes an optical area and the back plate 110 and reinforcement patterns have the structure illustrated in FIG. 3. Further, in the reinforcement patterns of the display device 100 according to Example 1, A1 and B1 of FIG. 3 are the same, A2 and B2 are the same, A3 and B3 are the same, and A4 and B4 are the same. It is understood that in the second direction DR2, a maximum value of the tensile stress applied to the back plate 110 of Example 1 is 51.8 MPa and a stress improvement rate as compared with the back plate of Comparative Example is 28%.

In a display device according to Example 2, a back plate includes an optical area and the back plate 110 and reinforcement patterns with the structure illustrated in FIG. 4A are included below the display panel. It is understood that in the second direction DR2, a maximum value of the tensile stress applied to the back plate 110 of Example 2 is 53.8 MPa and a stress improvement rate as compared with the back plate of Comparative Example is 25%.

In a display device according to Example 3, a back plate 110 includes an optical area and the back plate 110 and reinforcement patterns having the structure illustrated in FIG. 3 are included below the display panel. Further, in the reinforcement patterns of the display device according to Example 3, A1 and B1 of FIG. 3 are the same, A2 and B2 are the same, A3 and B3 are the same, A4 and B4 are the same, and A1 and B1 are smaller than A2 and B2. It is understood that in the second direction DR2, a maximum value of the tensile stress applied to the back plate 110 of Example 3 is 51.0 MPa and a stress improvement rate as compared with the back plate of Comparative Example is 29%.

In a display device according to Example 4, a back plate 110 includes an optical area and the back plate 110 and reinforcement patterns having the structure illustrated in FIG. 3 are included below the display panel. Further, in the reinforcement patterns of the display device according to Example 4, A1 and B1 of FIG. 3 are the same, A2 and B2 are the same, A3 and B3 are the same, A4 and B4 are the same, and A3 and B3 are larger than A1 and B1. It is understood that in the second direction DR2, a maximum value of the tensile stress applied to the back plate 110 of Example 4 is 53.2 MPa and a stress improvement rate as compared with the back plate of Comparative Example is 26%.

In a display device according to Example 5, a back plate 110 includes an optical area and the back plate 110 and reinforcement patterns having the structure illustrated in FIG. 3 are included below the display panel. Further, in the reinforcement patterns of the display device according to Example 5, A1 and B1 of FIG. 3 are the same, A2 and B2 are the same, A4 and B4 are the same, and A3 is larger than A1, B1, A2, B2, B3, A4, and B4. It is understood that in the second direction DR2, a maximum value of the tensile stress applied to the back plate 110 of Example 5 is 52.3 MPa and a stress improvement rate as compared with the back plate of Comparative Example is 27%.

In a display device according to Example 6, a back plate 110 includes an optical area and the back plate 110 and reinforcement patterns having the structure illustrated in FIG. 3 are included below the display panel. Further, in the reinforcement patterns of the display device according to Example 6, A1 and B1 of FIG. 3 are the same, A2 and B2 are the same, A4 and B4 are the same, and B3 is larger than A1, B1, A2, B2, A3, A4, and B4. It is understood that in the second direction DR2, a maximum value of the tensile stress applied to the back plate 110 of Example 6 is 51.1 MPa and a stress improvement rate as compared with the back plate of Comparative Example is 29%.

In a display device according to Example 7, a back plate 110 includes an optical area and the back plate 110 and reinforcement patterns having the structure illustrated in FIG. 3 are included below the display panel. Further, in the reinforcement patterns of the display device according to Example 7, A1 and B1 of FIG. 3 are the same, A4 and B4 are the same, and B2 is larger than A2, and B4 is larger than A4. It is understood that in the second direction DR2, a maximum value of the tensile stress applied to the back plate 110 of Example 7 is 48.7 MPa and a stress improvement rate as compared with the back plate of Comparative Example is 32%.

In a display device according to Example 8, a back plate 110 includes an optical area and the back plate 110 and reinforcement patterns having the structure illustrated in FIG. 3 are included below the display panel. Further, in the reinforcement patterns of the display device according to Example 8, A1 and B1 of FIG. 3 are the same, A4 and B4 are the same, and A2 is larger than B2, and A4 is larger than B4. It is understood that in the second direction DR2, a maximum value of the tensile stress applied to the back plate 110 of Example 8 is 50.2 MPa and a stress improvement rate as compared with the back plate of Comparative Example is 30%.

In a display device according to Example 9, a back plate 110 includes an optical area and the back plate 110 and reinforcement patterns having the structure illustrated in FIG. 3 are included below the display panel. Further, in the reinforcement patterns of the display device according to Example 9, A1 and B1 of FIG. 3 are the same, A2 and B2 are the same, A3 and B3 are the same, A4 and B4 are the same, and A2 and B2 are larger than A4 and B4. It is understood that in the second direction DR2, a maximum value of the tensile stress applied to the back plate 110 of Example 9 is 49.6 MPa and a stress improvement rate as compared with the back plate of Comparative Example is 31%.

In a display device according to Example 10, a back plate 110 includes an optical area and the back plate 110 and reinforcement patterns having the structure illustrated in FIG. 3 are included below the display panel. Further, in the reinforcement patterns of the display device according to Example 10, A1 and B1 of FIG. 3 are the same, A2 and B2 are the same, A3 and B3 are the same, A4 and B4 are the same, and A4 and B4 are larger than A2 and B2. It is understood that in the second direction DR2, a maximum value of the tensile stress applied to the back plate 110 of Example 10 is 49.4 MPa and a stress improvement rate as compared with the back plate of Comparative Example is 31%.

In a display device according to Example 11, a back plate includes an optical area and the back plate 110 and reinforcement patterns with the structure illustrated in FIG. 4B are included below the display panel. It is understood that in the second direction DR2, a maximum value of the tensile stress applied to the back plate 110 of Example 11 is 56.8 MPa and a stress improvement rate as compared with the back plate of Comparative Example is 21%.

In a display device according to Example 12, a back plate includes an optical area and the back plate 110 and reinforcement patterns with the structure illustrated in FIG. 4C are included below the display panel. It is understood that in the second direction DR2, a maximum value of the tensile stress applied to the back plate 110 of Example 12 is 63.1 MPa and a stress improvement rate as compared with the back plate of Comparative Example is 12%.

In a display device according to Example 13, a back plate includes an optical area and the back plate 110 and reinforcement patterns with the structure illustrated in FIG. 4D are included below the display panel. It is understood that in the second direction DR2, a maximum value of the tensile stress applied to the back plate 110 of Example 13 is 58.7 MPa and a stress improvement rate as compared with the back plate of Comparative Example is 18%.

As described above, the display device includes reinforcement patterns disposed on the same layer as the back plate 110 to improve rigidity of the back plate and the display panel in the vicinity of the optical area OA.

The exemplary embodiments of the present disclosure can also be described as follows:

According to an embodiment of the present disclosure, there is provided a display device. The display device includes a display panel including a display area and an optical are. The display device further includes a back plate disposed below the display panel. The display device further includes a first reinforcement pattern which encloses the optical area and is a closed curve line on the plane. The first reinforcement pattern is disposed on the same layer as the back plate and the back plate is disposed between the optical area and the first reinforcement pattern on the plane.

A rigidity of the first reinforcement pattern may be larger than a rigidity of the back plate.

The display device may further include a plurality of extension reinforcement patterns which extends from the first reinforcement pattern in a first direction or a second direction which is different from the first direction. The first reinforcement pattern may include a first part extending in the first direction, a second part which extends in the second direction and may be connected to one end of the first part, a third part which extends in the first direction and may be connected to one end of the second part, and a fourth part which extends in the second direction and may be connected to one end of the third part and the other end of the first part, and the plurality of extension reinforcement patterns may extend from at least one of the first part, the second part, the third part, and the fourth part.

A distance from the first part and the third part to the optical area may be equal to or smaller than a distance from the second part and the fourth part to the optical area.

The distance from the first to fourth parts to the optical area may be smaller than widths of the first part and the third part in the second direction and widths of the second part and the fourth part in the first direction.

The display device may further include at least one second reinforcement pattern which encloses at least a part of the first reinforcement pattern. The first reinforcement pattern may include a first part extending in the first direction, a second part which extends in the second direction and may be connected to one end of the first part, a third part which extends in the first direction and may be connected to one end of the second part, and a fourth part which extends in the second direction and may be connected to one end of the third part and the other end of the first part, and the second reinforcement pattern may be spaced apart from at least one of the first part, the second part, the third part, and the fourth part.

The back plate and the plurality of extension reinforcement patterns may be disposed in an area between the second reinforcement pattern and the first reinforcement pattern.

A distance between the first reinforcement pattern and the second reinforcement pattern in the first and second directions may be larger than a width of the first reinforcement pattern and a width of the second reinforcement pattern in the first and second directions.

The plurality of extension reinforcement patterns may include a first extension reinforcement pattern extending from one side of the first part, a second extension reinforcement pattern extending from the other side of the first part, a third extension reinforcement pattern extending from one side of the second part, a fourth extension reinforcement pattern extending from the other side of the second part, a fifth extension reinforcement pattern extending from one side of the third part, a sixth extension reinforcement pattern extending from the other side of the third part, a seventh extension reinforcement pattern extending from one side of the fourth part and an eighth extension reinforcement pattern extending from the other side of the fourth part.

The second reinforcement pattern may include a fifth part extending in the first direction, a sixth part which extends in the second direction and may be connected to one end of the fifth part, a seventh part which extends in the first direction and may be connected to one end of the sixth part, and an eighth part which extends in the second direction and may be connected to one end of the seventh part and the other end of the fifth part, and the fifth part may be connected to the fourth and seventh extension reinforcement patterns, the sixth part may be connected to the first and sixth extension reinforcement patterns, the seventh part may be connected to the third and eighth extension reinforcement patterns, and the eighth part may be connected to the second and fifth extension reinforcement patterns.

The display device may further include at least one additional extension reinforcement pattern which extends in a direction between the first direction and the second direction between the first reinforcement pattern and the second reinforcement pattern. The second reinforcement pattern may be connected to the additional extension reinforcement pattern.

A width of the second reinforcement pattern in the first direction and the second direction may be larger than a width of the first reinforcement pattern or a width of the extension reinforcement pattern in the first direction and the second direction.

Widths in the second direction of a part of the first reinforcement pattern and a part of the second reinforcement pattern extending in the first direction may be larger than widths in the first direction of a part of the first reinforcement pattern and a part of the second reinforcement pattern extending in the second direction.

The non-display area may include a first separation area adjacent to the optical area, the first separation area may include at least one pattern, and the first reinforcement pattern, the extension reinforcement pattern, and the second reinforcement pattern may overlap at least one pattern disposed in the first separation area.

A rigidity of the extension reinforcement pattern and the second reinforcement pattern may be larger than a rigidity of the back plate.

In the display area, a part of at least one of the first reinforcement pattern, the plurality of extension reinforcement patterns, and the second reinforcement pattern may be disposed and the optical area may be a hole included in the display panel and the back plate.

The display device may further include a metal member disposed below the first reinforcement pattern, an extension area, and the back plate. The first reinforcement pattern and the extension area may be integrated with the metal member.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a display panel including a display area and an optical area;
a back plate below the display panel; and
a first reinforcement pattern that encloses the optical area and is a closed curve line on a plane,
wherein the first reinforcement pattern is on a same layer as the back plate and the back plate is between the optical area and the first reinforcement pattern on the plane.

2. The display device according to claim 1, wherein a rigidity of the first reinforcement pattern is greater than a rigidity of the back plate.

3. The display device according to claim 1, further comprising:
a plurality of extension reinforcement patterns that extend from the first reinforcement pattern in a first direction or a second direction which is different from the first direction,
wherein the first reinforcement pattern includes a first part extending in the first direction, a second part that extends in the second direction and is connected to one end of the first part, a third part that extends in the first direction and is connected to one end of the second part, and a fourth part that extends in the second direction and is connected to one end of the third part and another end of the first part, and the plurality of extension reinforcement patterns extend from at least one of the first part, the second part, the third part, and the fourth part.

4. The display device according to claim 3, wherein a distance from the first part and the third part to the optical area is equal to or smaller than a distance from the second part and the fourth part to the optical area.

5. The display device according to claim 3, wherein a distance from the first part to the fourth part to the optical area is smaller than widths of the first part and the third part in the second direction and widths of the second part and the fourth part in the first direction.

6. The display device according to claim 3, further comprising:
at least one second reinforcement pattern that encloses at least a part of the first reinforcement pattern,
wherein the first reinforcement pattern includes a first part extending in a first direction, a second part that extends in a second direction and is connected to one end of the first part, a third part that extends in the first direction and is connected to one end of the second part, and a fourth part that extends in the second direction and is connected to one end of the third part and another end of the first part, and
the at least one second reinforcement pattern is spaced apart from at least one of the first part, the second part, the third part, and the fourth part.

7. The display device according to claim 6, wherein the back plate and the plurality of extension reinforcement patterns are in an area between the at least one second reinforcement pattern and the first reinforcement pattern.

8. The display device according to claim 6, wherein a distance between the first reinforcement pattern and the at least one second reinforcement pattern in the first direction and the second direction is larger than a width of the first reinforcement pattern and a width of the at least one second reinforcement pattern in the first direction and the second direction.

9. The display device according to claim 6, wherein the plurality of extension reinforcement patterns include:
a first extension reinforcement pattern extending from one side of the first part;
a second extension reinforcement pattern extending from another side of the first part;
a third extension reinforcement pattern extending from one side of the second part;
a fourth extension reinforcement pattern extending from another side of the second part;
a fifth extension reinforcement pattern extending from one side of the third part;
a sixth extension reinforcement pattern extending from another side of the third part;
a seventh extension reinforcement pattern extending from one side of the fourth part; and
an eighth extension reinforcement pattern extending from another side of the fourth part.

10. The display device according to claim 9, wherein the at least one second reinforcement pattern includes a fifth part extending in the first direction, a sixth part that extends in the second direction and is connected to one end of the fifth part, a seventh part that extends in the first direction and is connected to one end of the sixth part, and an eighth part that extends in the second direction and is connected to one end of the seventh part and another end of the fifth part, and
the fifth part is connected to the fourth extension reinforcement pattern and the seventh extension reinforcement pattern,
the sixth part is connected to the first extension reinforcement pattern and the sixth extension reinforcement pattern,
the seventh part is connected to the third extension reinforcement pattern and the eighth extension reinforcement pattern, and
the eighth part is connected to the second extension reinforcement pattern and the fifth extension reinforcement pattern.

11. The display device according to claim 10, wherein the plurality of extension reinforcement patterns include:
a first extension reinforcement pattern extending from one side of the first part;
a second extension reinforcement pattern extending from another side of the first part;
a fourth extension reinforcement pattern extending from another side of the second part;
a fifth extension reinforcement pattern extending from one side of the third part;
a sixth extension reinforcement pattern extending from another side of the third part; and
a seventh extension reinforcement pattern extending from one side of the fourth part.

12. The display device according to claim 11, wherein the at least one second reinforcement pattern includes a fifth part extending in the first direction, a sixth part that extends in the second direction and is connected to one end of the fifth part, and an eighth part that extends in the second direction and is connected to one end of the seventh part and another end of the fifth part,
the fifth part is connected to the fourth extension reinforcement pattern and the seventh extension reinforcement pattern,
the sixth part is connected to the first extension reinforcement pattern and the sixth extension reinforcement pattern, and
the eighth part is connected to the fifth extension reinforcement pattern and the second extension reinforcement pattern.

13. The display device according to claim 6, further comprising:
at least one additional extension reinforcement pattern that extends in a direction between the first direction and the second direction between the first reinforcement pattern and the at least one second reinforcement pattern,
wherein the at least one second reinforcement pattern is connected to the at least one additional extension reinforcement pattern.

14. The display device according to claim 13, wherein a width of the at least one second reinforcement pattern in the first direction and the second direction is larger than a width of the first reinforcement pattern or a width of the at least one additional extension reinforcement pattern in the first direction and the second direction.

15. The display device according to claim 6, wherein widths in the second direction of a part of the first reinforcement pattern and a part of the at least one second reinforcement pattern extending in the first direction are larger than widths in the first direction of a part of the first reinforcement pattern and a part of the at least one second reinforcement pattern extending in the second direction.

16. The display device according to claim 13, wherein a non-display area includes a first separation area adjacent to the optical area, the first separation area includes at least one pattern, and the first reinforcement pattern, the at least one additional extension reinforcement pattern, and the at least one second reinforcement pattern overlap at least one pattern in the first separation area.

17. The display device according to claim 13, wherein a rigidity of the at least one additional extension reinforcement pattern and the at least one second reinforcement pattern is greater than a rigidity of the back plate.

18. The display device according to claim 6, wherein in the display area, a part of at least one of the first reinforcement pattern, the plurality of extension reinforcement patterns, and the at least one second reinforcement pattern is disposed and the optical area is a hole included in the display panel and the back plate.

19. The display device according to claim 1, further comprising:
a metal member below the first reinforcement pattern, an extension area, and the back plate,
wherein the first reinforcement pattern and the extension area are integrated with the metal member.
